(19) United States
(12) Patent Application Publication
(10) Pub. No.: US 2026/0251719 A1
(43) Pub. Date: Aug. 27, 2026

(54) VOLTAGE MONITORING ARRANGEMENT FOR AN ELECTRIC CELL STACK, PARTICULARLY FOR A FUEL CELL STACK

(71) Applicant: POWERCELL SWEDEN AB, 418 43 Gothenburg (SE)

(72) Inventors: Johan FLINK, Gothenburg (SE); Stefan MUNTHE, Västra Frölunda (SE); Robin VELÉN, Hovas (SE)

(73) Assignee: POWERCELL SWEDEN AB, 418 43 Gothenburg (SE)

(21) Appl. No.: 18/994,293

(22) PCT Filed: Jul. 5, 2023
(86) PCT No.: PCT/SE2023/050701

§ 371 Date: Jan. 14, 2025

(30) Foreign Application Priority Data
Jul. 18, 2022 (SE) 2250918-6

(51) Int. Cl. G01R 31/3835

(52) U.S. Cl. CPC G01R 31/3835

(57) ABSTRACT

A voltage monitoring arrangement for an electric cell stack including a plurality of electric plates sandwiching insulation layers is configured to monitor a voltage of at least one electric plate of the electric cell stack, wherein the voltage monitoring arrangement includes at least one voltage monitoring unit with a contact element being in contact with the at least one electric plate, wherein the voltage monitoring arrangement includes a first signal line being configured to supply a first signal from a signal source to a processing unit, wherein the voltage monitoring unit includes a first signal path interrupting element interposed in the first signal line, wherein the first signal path interrupting element is connected to the contact element and is configured to forward the first signal dependent on a voltage being present at the at least one electric plate.

### BACKGROUND AND SUMMARY

The present invention relates to a voltage monitoring arrangement for an electric cell stack, particularly for a fuel cell stack.

Usually, an electric cell stack comprises a plurality of stacked electric plates which are separated from each other by insulating layers. In the special case of a fuel cell stack, the electric plates are bipolar plates, and the insulating layers are multi-layer membrane electrode assemblies. The bipolar plates themselves are a combination of an anode plate and a cathode plate which are fixed to each other, wherein adjacent bipolar plates are then separated, or with other words sandwiched, by the membrane electrode assemblies. The cathode and anodes plate which form the bipolar plates are usually electrically transmitting metal or graphite plates, so called flow field plates, having a flow field for the reactants at one side and a flow field for a cooling fluid on the other side. In the assembled state of the membrane electrode assembly, the flow field plates are placed on top of each other in such a way that the cooling fluid flow fields are facing each other, and the reactant fluid flow fields face the sandwiching membrane electrode assemblies. The electric current produced by the membrane electrode assemblies during operation of the fuel cell stack results in a voltage potential difference between the bipolar plate assemblies.

During the operation of the electric cell stack, the voltage produced by the stacked cells needs to be monitored for determining whether the stack is operating within its intended operation parameters. For that, each electric plate is usually equipped with voltage monitoring units, which are fixed to the electric plate and are provided with wires for connecting the voltage monitoring units to an external voltage monitoring controller, which monitors and controls the operation of the stack.

The voltage of the electric cell stack may be monitored by measuring the voltage of each electric plate and comparing each measured voltage with a reference or threshold voltage. Alternatively, the voltages within a fuel cell stack may be measured by measuring the voltage of one plate in comparison with the voltage of the previous plate and by monitoring the differences. In any case, a measurement of the voltage of each plate is necessary and requires corresponding measurement means which are cost intensive.

It is therefore desirable to provide a voltage monitoring arrangement which is cost-efficient, and which can easily be implemented into an electric cell stack, and in particular into a fuel cell stack.

The voltage monitoring arrangement according to an aspect of the invention is configured to monitor a voltage of at least one electric plate of an electric cell stack. Such an electric cell stack may particularly be a fuel cell stack and may comprise a plurality of electric plates sandwiching insulation layers.

It should be noted that in general, in this application, the term “electric plate” does not necessarily refer to a rigid electric plate. Also, a flexible layer-like electric element (anode or cathode) may be named as electric plate in this application.

Additionally, the electric cell stack may be a fuel cell stack, wherein the electric plate is a bipolar plate consisting of or comprising an anode plate and a cathode plate, which are fixed to each other. Further in that case, the insulating layers are multilayer membrane electrode assemblies. The bipolar plates are usually rigid metal or graphite plates which are provided with flow field structures for providing and distributing reactant and/or coolant to the bipolar plate and/or to the adjacent membrane electrode assemblies.

The voltage monitoring arrangement comprises at least one voltage monitoring unit with a contact element. The contact element is connected to the at least one of the plurality of electric plates for example in the form of a pin or any other kind of connector or may be directly welded to the at least one electric plate. In a preferred embodiment as described below, there is more than one voltage monitoring unit, each having a contact element, wherein each of the contact elements is connected to one of the plurality of electric plates.

For monitoring the voltage of the electric cell stack, the voltage monitoring arrangement comprises a first signal line being configured to supply a first signal from a signal source to a processing unit, wherein the voltage monitoring unit comprises a first signal path interrupting element interposed in the first signal line, wherein the first signal path interrupting element is connected to the contact element and is configured to forward the first signal dependent on a voltage being present at the electric plate.

Thus, instead of directly measuring and monitoring the voltage of the electric plate, the herein proposed voltage monitoring arrangement uses an indirect monitoring approach. A first signal is transmitted on the first signal line to the processing unit. The first signal itself is applied to the first signal line independent on the voltages of the electric plates. For example, the first signal on the first signal line may originate from an optical or electrical source, like a current or voltage source.

Alternatively, the signal source may be a first electric plate of the plurality of electric plates. This means that the first signal may originate from the first electric plate and may be supplied to the first signal line and then serves as the first signal on the signal line. The transmission on the first signal line may then be interrupted or the first signal may be forwarded using further voltage monitoring units and corresponding signal path interrupting elements of further electric plates as will be described in the following.

The transmission of the first signal on the first signal line however depends on the voltages of the electric plates as will be described in the following: A voltage of the at least one electric plate is tapped by the contact element and transmitted to the first signal path interrupting element. The first signal path interrupting element will then close, i.e., connect through, or open, i.e., interrupt, the first signal line dependent on the tapped voltage of the at least one electric plate. Alternatively, the first signal path interrupting element may open for forwarding the signal on the first signal line and close for interrupting the first signal line dependent on the tapped voltage of the at least one electric plate. When the first signal path interrupting element closes the first signal line, the first signal will be forwarded to the processing unit. When the first signal path interrupting element opens, i.e., interrupts the first signal line, the first signal will not be forwarded to the processing unit.

In the processing unit, it may then only be monitored whether the first signal is received or not. If the processing unit does not receive any signal, there is no voltage present at the at least one electric plate, or the voltage is too low, and this may be interpreted as an electric plate which is not performing as intended, i.e., not operating within its intended operation parameters. Alternatively, depending on the implementation of the signal path interrupting element as described above, if the processing unit receives a signal, there might be no voltage present at the at least one electric plate, or the voltage might be too low, and this may be interpreted as an electric plate which is not performing as intended. For example, this may be the case inter alia if the electric plate is defective. Thus, the proposed voltage monitoring arrangement provides an easy and cost-efficient way of monitoring the voltage of an electric plate, without the need of an actual measuring of the electric plate voltage.

Alternatively, depending on the implementation of the signal path interrupting element as described above, if the processing unit receives a signal, there might be no voltage present at the at least one electric plate, or the voltage might be too low, and this may be interpreted as an electric plate which is not performing as intended. Thus, the signal path interrupting element in combination with the signal line may forward the signal on the first signal line if the electric plate operates as intended and may not forward the signal (i.e., interrupt the signal line) if the electric plate operates not as intended. Or, vice versa, the signal path interrupting element in combination with the signal line may not forward the signal on the first signal line, i.e., interrupt the signal line, if the electric plate operates as intended, and forward a signal if the electric plate operates not as intended. Thus, in the first exemplary implementation, the processing unit may determine that the electric plate is not performing as intended when no signal is received and, in the second exemplary implementation, the processing unit may determine that that electric plate is not performing as intended when a signal is received. It should be noted that in the following, both implementations may be equivalently used and, when only one possible implementation is described, the same features and examples apply also to the other implementation.

According to an embodiment, the first signal path interrupting element is configured to forward or to interrupt the first signal, when the voltage being present at the at least one electric plate is above a reference threshold voltage. Vice versa, when the voltage being present at the at least one electric plate is below the reference threshold voltage, the first signal path interrupting element may be configured to interrupt a signal transmission on the first signal line or to forward the signal. The reference threshold voltage may be a voltage which is considered to delimit a normal operating voltage or voltage range of the at least one electric plate from a voltage being indicative for a defect of the at least one electric plate.

According to a further embodiment, the first signal is an electrical signal, and the first signal path interrupting element is a relay, electrical switch, or electro-mechanical switch. The electrical signal may be a voltage or current signal which can be received in the processing unit. The first signal path interrupting element may be any kind of switch-like element which is able to interrupt a signal transmission of the first signal on the first signal line or to direct the first signal through. For example, the signal path interrupting element may be a relay, for example, in the form of a transistor, in particular a bipolar transistor. The relay may be operated or switched by the voltage being present at the electric plate. For example, in case the relay is a transistor, the voltage at the electric plate may be applied to the base of the transistor and the transistor may then connect through, particularly when the voltage on the at least one electric plate is above the reference threshold. Subsequently, the first signal is transmitted through the transistor in the first signal line and forwarded to the processing unit.

According to an alternative embodiment, the first signal may be an optical signal and the signal path interrupting element may be an electrical or electro-mechanical switch, for example a piezo element. In this case, the first signal line may be an optical fiber or the like transmitting an optical signal and the signal path interrupting element may be configured to interrupt the propagation of the optical signal on the first signal line. For example, when using a piezo element, which is an electro-mechanical switch being activated by a voltage, the piezo element may be influenced by a voltage being present or being absent (depending on the actual implementation) and may then open or close the optical path.

According to a further embodiment, the voltage monitoring unit further comprises a voltage fluctuation levelling element being arranged between the contact element and the first signal path interrupting element and being configured to transmit the voltage from the contact element to the first signal path interrupting element when the voltage is above a levelling threshold voltage. Such a voltage fluctuation levelling element may be implemented for example using a resistor or any kind of filtering element being able to equalize voltage fluctuations. The voltage fluctuation levelling element may be used for eliminating voltage fluctuations, i.e., to level out the voltage fluctuations. Such fluctuations may cause that the first signal path interrupting element very often switches between its two different stages, although the voltage does not change much but only within a small range, e.g., caused by typical fluctuations without a deterioration of the at least one electric plate. When such a voltage fluctuation levelling element is used, it may be avoided that the first signal path interrupting element switches between its two stages without being caused by a deterioration of the at least one electric plate. As unnecessary switching of the first signal path interrupting element may be reduced by the voltage fluctuation levelling element, the first signal path interrupting element may also be protected as voltage fluctuations may be filtered and does not influence the signal path interrupting element being downstream of the voltage fluctuation levelling element. Reduced switching of the signal path interrupting element may increase the lifetime of the signal path interrupting element.

According to a further embodiment, the voltage monitoring unit, i.e., the combination of voltage fluctuation levelling element and signal path interrupting element, may be used for defining the reference threshold voltage, below which the electric plate may be considered as not performing as intended. This means, that, when the at least one electric plate generates a voltage below such a reference threshold voltage, the signal path interrupting element may interrupt the signal transmission on the signal line or, alternatively, may forward the signal on the signal line.

According to a further embodiment, the processing unit is configured to output a warning signal if the first signal is not forwarded to the processing unit. As already described above, the processing unit may determine that at least one of the electric plates is not performing as intended if the processing unit does not receive the first signal. In this case, the processing unit may output a warning signal indicating that at least one electric plate is not performing as intended. Alternatively, the processing unit may output a warning signal when the first signal is received, as described above.

According to a further embodiment, the voltage monitoring arrangement comprises a plurality of voltage monitoring units, each of which comprises a contact element being in contact with one of the plurality of electric plates. Further, each voltage monitoring unit comprises a first signal path interrupting element interposed in the first signal line, which is connected to the contact element and is configured to forward the first signal dependent on a voltage being present at the respective electric plate. The first signal path interrupting elements of all voltage monitoring units are connected in series. Thus, if one of the electric plates is not performing as intended, the voltage generated by the electric plate which is not performing as intended will be below the above-mentioned reference threshold voltage and the corresponding first signal path interrupting element will interrupt the first signal line and no first signal will be received at the processing unit. Vice versa, the first signal path interrupting elements will connect the first signal through when the voltage generated by the respective electric plate is above the reference threshold voltage. In this case, the processing unit will receive the first signal. As described above, the interruption and forwarding of the signal transmission may also be reversed, i.e., a signal may be forwarded if the electric plate does not perform as intended and no signal may be forward if the electric plate performs as intended.

Thus, instead of monitoring the exact voltage of each electric plate, it is sufficient to monitor the voltages of the electric plate in a more abstract manner. As it is necessary to disassemble the complete electrical cell stack when one of the electric plates is not performing as intended, it is sufficient to monitor the voltages of all electric plates as a whole. When one of the electric plates is not performing as intended, the first signal is not forwarded to the processing unit (or alternatively the first signal is forwarded as described above) and the processing unit thus determines that at least one electric plate is not performing as intended, which means that the whole stack is not performing as intended, although it is not known which electric plate is not performing as intended. In this case, the whole electrical cell stack may be disassembled and then, each electric plate may be checked regarding its functionality. Thus, the herein described voltage monitoring arrangement provides an easy and cost-efficient way of monitoring the electrical cell stack. Alternatively, before disassembling the whole electrical cell stack, an additional evaluation unit may be installed for evaluating each electric plate separately. For example, such an evaluation unit may be attached to each electric plate for further inspection.

In another embodiment, only some of the voltage monitoring units comprise a signal path interrupting element. According to this embodiment, some of the voltage monitoring units only comprise a contact element for tapping the voltage of the corresponding electric plate. The tapped voltages of several consecutive electric plates are transmitted to the respective one of the voltage monitoring units which comprises a signal path interrupting element. This voltage monitoring unit switches the signal path interrupting element based on an accumulated total voltage of the preceding electric plates. Thus, instead of interrupting the first signal line when the voltage of the corresponding electric plate is below the defined threshold, the voltage monitoring unit interrupts the first signal line when the accumulated total voltage of the preceding electric plates is below a predefined threshold. Alternatively, the voltage monitoring unit may forward the signal on the first signal line when the accumulated total voltage of the preceding electric plates is below a predefined threshold.

For example, each fifth voltage monitoring unit comprises a signal path interrupting element. The first to fourth voltage monitoring unit taps the voltage of the corresponding electric plates and forwards the tapped voltage to the fifth voltage monitoring unit. The fifth voltage monitoring unit switches the signal path interrupting element when the accumulated voltage of the first to fourth and fifth electric plate is below or above the predefined threshold, as described above.

According to a further embodiment, the voltage monitoring arrangement comprises a second signal line being connected in parallel with the first signal line. In this embodiment, the voltage monitoring unit comprises a second signal path interrupting element being interposed in the second signal line and being connected in parallel with the first signal path interrupting element. The first and the second signal path interrupting element may be adapted to different threshold voltages so that a more detailed monitoring of the electric plates is realized.

For example, the first signal path interrupting element may be configured to forward (or interrupt) the first signal when the voltage at the electric plate is above a first reference voltage and the second signal path interrupting element may be configured to forward (or interrupt) the second signal when the voltage at the electric plate is above a second reference voltage. Preferably, the first reference voltage and the second reference voltage are different to each other. This provides the advantage that different warning stages may implemented. For example, the first signal path interrupting element may serve as a first warning stage so that the first signal path interrupting element interrupts the transmission of the first signal when the voltage generated by the electric plate drops below a higher reference threshold voltage. This higher reference threshold voltage may indicate that the electrical cell stack is, although still functioning, reaching a critical state. When the generated voltage drops also below the lower reference threshold voltage of the second signal path interrupting element, the processing unit may determine that the electric cell stack needs to be disassembled and at least one of the electric plates needs to be replaced.

The voltage monitoring arrangement may be scalable as needed, for example by a third signal line and a third signal path interrupting element, a fourth signal line and a fourth signal path interrupting element and so on. The more signal lines and corresponding signal path interrupting elements are used, the more different warning stages may be implemented.

It should be noted that in this embodiment, when several voltage monitoring units are used, the first signal path interrupting elements of all voltage monitoring units are connected in series, the second signal path interrupting elements of all voltage monitoring units are connected in series, and so on.

Further preferred embodiments are defined in the dependent claims as well as in the description and the figures. Thereby, elements described or shown in combination with other elements may be present alone or in combination with other elements without departing from the scope of protection.

### BRIEF DESCRIPTION OF THE DRAWINGS

In the following, preferred embodiments of the invention are described in relation to the drawings, wherein the drawings are exemplarily only, and are not intended to limit the scope of protection. The scope of protection is defined by the accompanied claims, only.

The figures show:

FIG. 1: a first embodiment of a voltage monitoring arrangement for an electric cell stack;

FIG. 2: a second embodiment of a voltage monitoring arrangement for an electric cell stack; and

FIG. 3: a third embodiment of a voltage monitoring arrangement for an electric cell stack.

### DETAILED DESCRIPTION

In the following same or similar functioning elements are indicated with the same reference numerals.

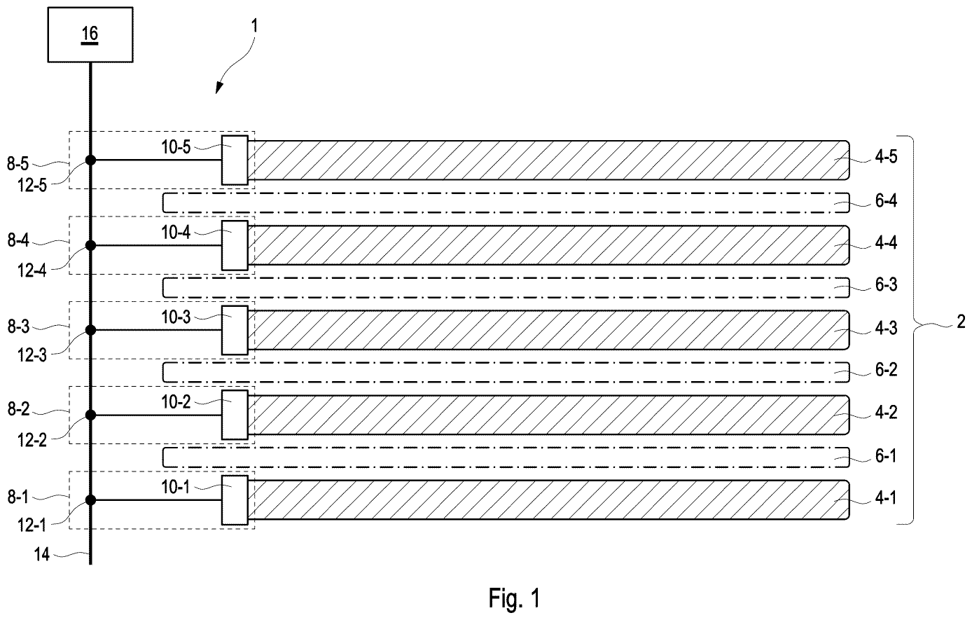

FIG. 1 shows a voltage monitoring arrangement 1 for an electric cell stack 2, for example a fuel cell stack. The electric cell stack 2 comprises a plurality of electric plates 4-1 to 4-5 sandwiching insulation layers 6-1 to 6-4.

The electric cell stack 2 generates a total voltage as a result of individual voltages of each electric plate 4-1 to 4-5. As the electric plates 4-1 to 4-5 may wear over time and the generated total voltage depends on each electric plate 4-1 to 4-5, it is necessary to monitor the generated voltages.

For this purpose, the voltage monitoring arrangement 1 comprises several voltage monitoring units 8-1 to 8-5, preferably one for each electric plate 4-1 to 4-5. Each voltage monitoring unit 8-1 to 8-5 comprises a contact element 10-1 to 10-5. Each contact element 10-1 to 10-5 is connected to one of the plurality of electric plates 4-1 to 4-5, for example in the form of a pin or any other kind of connector or may be directly welded to the electric plate. Alternatively, the contact elements 10-1 to 10-2 are arranged at the respective electric plate 4-1 to 4-5 for example via molding, preferably injection molding.

Via the contact elements 10-1 to 10-5, the respective voltages of the electric plates 4-1 to 4-5 are tapped and transmitted to first signal path interrupting elements 12-1 to 12-5. The first signal path interrupting elements 12-1 to 12-5 are interposed in a first signal line 14, which is configured to transmit a first signal to a processing unit 16.

In the following, the signal is an electrical signal, and the signal path interrupting elements are electrical switches, for example transistors. However, it should be noted that the signal may also be an optical signal and the signal path interrupting elements may also be electro-mechanical switches, like piezo elements, or the like. The following description also applies to such an embodiment. Further, in the following, the signal path interrupting elements are configured to interrupt a signal transmission when one electric plate is not performing as intended. However, the following description may analogously be applied to an embodiment where the signal path interrupting elements are configured to forward the signal when an electric plate does not perform as intended and to interrupt the signal transmission when the electric plates perform properly.

The signal may originate from an electric source, for example a voltage supply. Alternatively, the voltage of the first electric plate 4-1 may be used as the signal to be transmitted on the signal line 14. The first signal line 14 supplies the first signal to the processing unit 16. The processing unit 16 can determine, based on the received signal, whether the electric cell stack 2 operates properly, as will be described in further detail in the following.

The first signal path interrupting elements 12-1 to 12-5 receive the respective voltages of the electric plates 4-1 to 4-5 via the contact elements 10-1 to 10-5. Dependent on the respective voltage, each of the first signal path interrupting elements 12-1 to 12-5 either forwards the signal on the first signal line 14 or interrupts the transmission. When all generated voltages are sufficient, all first signal path interrupting elements 12-1 to 12-4 forward the signal to the respective next first signal path interrupting element 12-2 to 12-5 and the last one 12-5 of the first signal path interrupting elements forwards the signal to the processing unit 16.

The signal path interrupting elements 12-1 to 12-5 may be realized for example using electrical switches which open when the voltage is below a threshold and close when the voltage is above the threshold. In the first case, the signal line 14 is interrupted, and in the second case, the signal line 14 is closed and the signal may be forward to the respective next signal path interrupting element 12-2 to 12-5. For example, the signal path interrupting elements 12-1 to 12-5 may be transistors, wherein the voltage from the contact elements 10-1 to 10-5 is applied to the bases of the transistors, resulting in a voltage flow from emitter to collector or vice versa depending on the transistor type-when the applied voltage is above the threshold.

When the voltage of for example the electric plate 4-2 drops below a reference threshold voltage, the corresponding first signal path interrupting element 12-2 interrupts the transmission of the signal on the first signal line 14. In this case, although the other first signal path interrupting elements 12-1, 12-3 to 12-5 would still be closed, i.e., would still connect the first signal line 14 though and would therefore still forward the signal, the processing unit 16 does not receive any signal as the first signal line 14 is interrupted by the first signal path interrupting element 12-2. The processing unit 16 may then output a warning signal that at least one of the electric plates 4-1 to 4-5 is not performing as intended.

The processing unit 16 cannot determine which electric plate 4-1 to 4-5 is not performing as intended but can only determine that any plate is not performing as intended. However, it has been noted that this information is sufficient as in any case, the whole electric cell stack might need to be disassembled. A further detailed evaluation of the electric plates 4-1 to 4-5 can be done after disassembly of the whole stack 2. Alternatively, a further detailed evaluation can be done by installing an additional evaluation unit for evaluating each electric plate separately, prior to a disassembly of the whole electric cell stack. For example, such an evaluation unit may be attached to each electric plate 4-1 to 4-5 for further inspection of the individual electric plates 4-1 to 4-5.

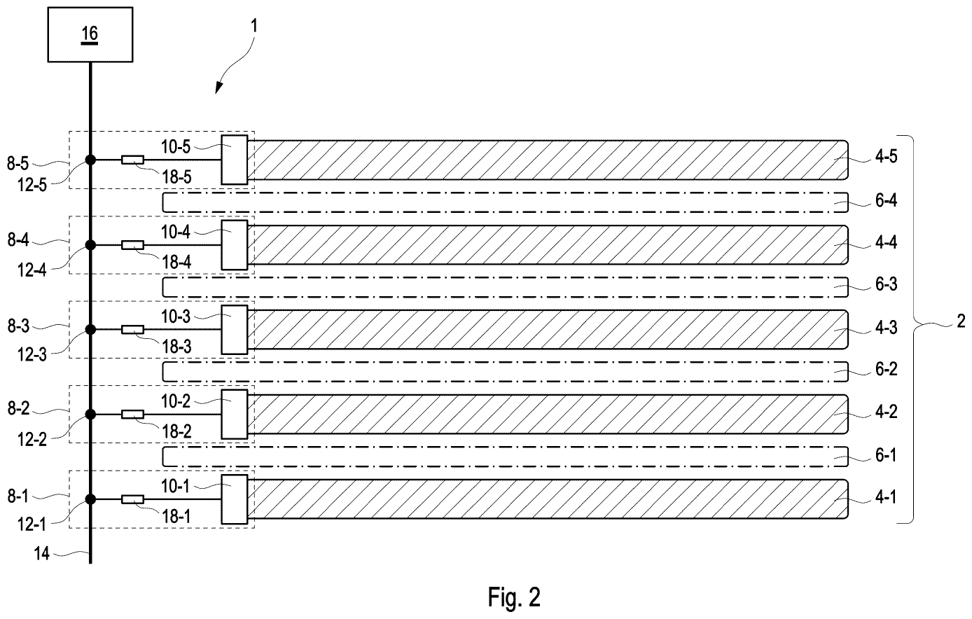

The voltage monitoring arrangement 1 can also comprise voltage fluctuation levelling elements 18-1 to 18-5 for protecting the first signal path interrupting elements 12-1 to 12-5, as shown in FIG. 2. The voltage fluctuation levelling elements 18-1 to 18-5 are connected in series between the contact elements 10-1 to 10-5 and the first signal path interrupting elements 12-1 to 12-5 and are configured to transmit the voltage from the respective contact elements 10-1 to 10-5 to the first signal path interrupting elements 12-1 to 12-5 when the voltage is above a levelling threshold voltage. Thus, voltage fluctuations may be filtered and does not influence the downstream signal path interrupting elements 12-1 to 12-5. The voltage fluctuation levelling elements 18-1 to 18-5 may be for example resistors.

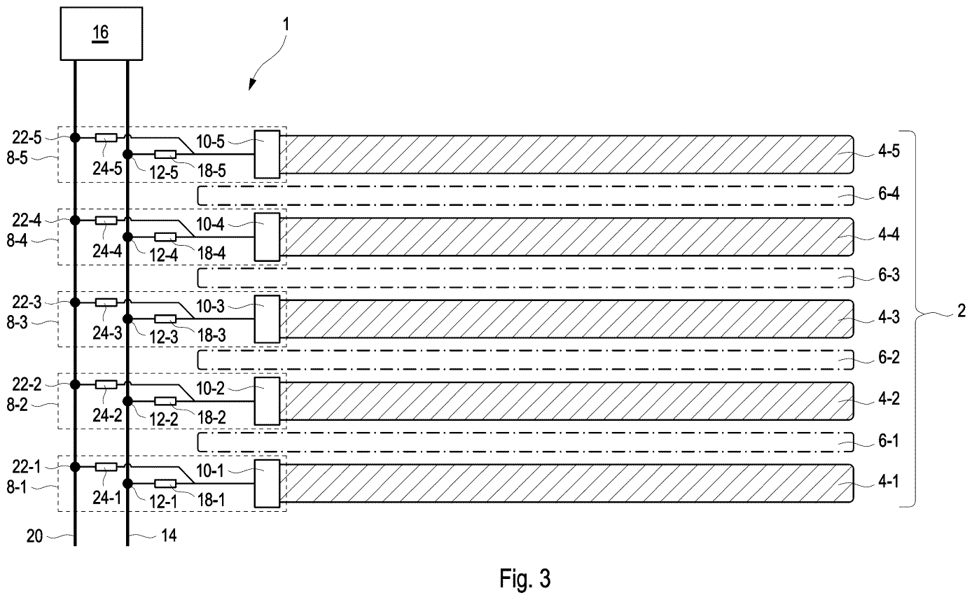

In a further embodiment, as illustrated in FIG. 3, the voltage monitoring arrangement 1 comprises an additional second signal line 20 being connected in parallel to the first signal line 14 and being also connected to the processing unit 16. The signal being transmitted on the first signal 14 may have the same origin as the signal being transmitted on the second signal line 20 or may have a different origin, for example a voltage source.

Each voltage monitoring unit 8-1 to 8-5 comprises a second signal path interrupting element 22-1 to 22-5, which are interposed in the second signal line 20 and are connected in parallel with the respective first signal path interrupting elements 12-1 to 12-5. Preferably, the first and the second signal path interrupting elements 12-1 to 12-5 and 22-1 to 22-5 are adapted to different threshold reference voltages.

As described with reference to FIG. 2, each voltage monitoring unit 8-1 to 8-5 may also comprise a second voltage fluctuation levelling element 24-1 to 24-5, being connected in series between the contact elements 10-1 to 10-5 and the second signal path interrupting elements 22-1 to 22-5. Analogously to the voltage fluctuation levelling elements 18-1 to 18-5, the second voltage fluctuation levelling elements 24-1 to 24-5 also serve as protection for the second signal path interrupting elements 22-1 to 22-5 by filtering voltage fluctuations. It should be noted that the voltage fluctuation levelling elements 18-1 to 18-5 and 24-1 to 24-5 are optional and can also be omitted.

The first and the second signal line 14, 20 may be used to provide a step-line warning system. This means that the first signal line 14 and the second signal line 20 with their corresponding signal path interrupting elements 12-1 to 12-5 and 22-1 to 22-5 are each adapted to a different reference voltage threshold. For example, when the voltage generated by one (e.g., 4-2) of the electric plates 4-1 to 4-5 drops below a first reference threshold voltage, the corresponding first signal path interrupting element 12-2 interrupts the transmission of the first signal as the voltage supplied to the first signal path interrupting element 12-2 is below the required first reference threshold voltage. Thus, the signal transmission on the first signal line 14 is interrupted and the processing unit 16 determines that the signal on signal line 20 is received but the signal on signal line 14 is not received. The processing unit 16 may then output a pre-warning signal indicating that one of the electric plates 4-1 to 4-5 has reached a critical state but is still functioning.

When the voltage generated by the electric plate 4-2 also drops below a second, lower reference threshold voltage, the corresponding second signal path interrupting element 22-2 interrupts the transmission also on the second signal line 20 and the processing unit 16 determines that the electric cell stack 2 needs to be disassembled and at least one of the electric plates 4-1 to 4-5 needs to be replaced.

The voltage monitoring arrangement 1 may comprise more than two signal lines 14, 20 with corresponding signal path interrupting elements and can therefore be upscaled as necessary. Dependent on the number of signal lines, a more detailed monitoring with different warning stages can be implemented.

In summary, with the herein described voltage monitoring arrangement, an easy and cost-efficient way of monitoring the voltages of an electric cell stack may be provided. Instead of monitoring the exact voltage of each electric plate, it is sufficient to monitor only whether any one of the electric plates in the electric cell stack is not performing as intended, without more detailed information with respect to the actual plate being responsible for not performing as intended.

### REFERENCE NUMERALS

1 voltage monitoring arrangement
2 electric cell stack
4 electric plate
6 insulation layer
8 voltage monitoring unit
10 contact element
12 first signal path interrupting element
14 first signal line
16 processing unit
18 voltage fluctuation levelling element
20 second signal line
22 second signal path interrupting element
24 voltage fluctuation levelling element

1. Voltage monitoring arrangement for an electric cell stack comprising
a plurality of electric plates sandwiching insulation layers wherein the voltage monitoring arrangement is configured to monitor a voltage of at least one electric plate of the electric cell stack,
at least one voltage monitoring unit with a contact element being in contact with the at least one electric plate,
a first signal line being configured to supply a first signal from a signal source to a processing unit,
a first signal path interrupting element interposed in the first signal line, wherein the first signal path interrupting element is connected to the contact element and is configured to forward the first signal dependent on a voltage being present at the at least one electric plate.

2. Voltage monitoring arrangement according to claim 1, wherein the first signal path interrupting element is configured to forward or to interrupt the first signal when the voltage being present at the at least one electric plate is above a reference threshold voltage.

3. Voltage monitoring arrangement according to claim 1, wherein the first signal is an electrical signal and wherein the first signal path interrupting element is a relay, electrical switch, or electro-mechanical switch.

4. Voltage monitoring arrangement according to claim 3, wherein the relay is a transistor, in particular a bipolar transistor.

5. Voltage monitoring arrangement according to claim 1, wherein the first signal is an optical signal and wherein the first signal path interrupting element is an electrical or electro-mechanical switch.

6. Voltage monitoring arrangement according to claim 1, wherein the signal source is a current or voltage source or is a first electric plate of the plurality of electric plates.

7. Voltage monitoring arrangement according to claim 1, wherein the voltage monitoring unit comprises a voltage fluctuation levelling element being arranged between the contact element and the first signal path interrupting element and being configured to transmit the voltage from the contact element to the first signal path interrupting element when the voltage is above a levelling threshold voltage.

8. Voltage monitoring arrangement according to claim 1, wherein the processing unit is configured to output a warning signal if the first signal is not forwarded to the processing unit or if the first signal is forwarded to the processing unit.

9. Voltage monitoring arrangement according to claim 1, wherein the voltage monitoring arrangement comprises a plurality of voltage monitoring units each comprising a contact element being in contact with a respective one of the plurality of electric plates and each comprising a first signal path interrupting element interposed in the first signal line wherein the respective first signal path interrupting element is connected to the corresponding contact element and is configured to forward the first signal dependent on a voltage being present at the respective electric plate wherein the first signal path interrupting elements of the plurality of voltage monitoring units are connected in series.

10. Voltage monitoring arrangement according to claim 1, wherein the voltage monitoring arrangement comprises a second signal line being connected in parallel with the first signal line and wherein the voltage monitoring unit comprises a second signal path interrupting element, which is interposed in the second signal line and is connected in parallel with the first signal path interrupting element.

11. Voltage monitoring arrangement according to claim 10, wherein the first signal path interrupting element is configured to forward the first signal when the voltage at the at least one electric plate is above a first reference threshold voltage and wherein the second signal path interrupting element is configured to forward or to interrupt the second signal when the voltage at the at least one electric plate is above a second reference threshold voltage.
